(19) United States
(12) Patent Application Publication
(10) Pub. No.: US 2008/0012589 A1
(43) Pub. Date: Jan. 17, 2008

(54) Wafer test card applicable for wafer test

(75) Inventor: Sung-Lai Wang, Wu Gu Shiang (TW)

Correspondence Address: BACON & THOMAS, PLLC, 625 SLATERS LANE, FOURTH FLOOR, ALEXANDRIA, VA, 22314, US

(73) Assignees: Sung-Lai Wang, Wu Gu Shiang (TW); Lih Duo International Co., Ltd., Wu Gu Shiang (TW)

(21) Appl. No.: 11/702,205

(22) Filed: Feb. 5, 2007

(30) Foreign Application Priority Data
Jul. 13, 2006 (TW) 095212328

(51) Int. Cl. G01R 1/073

(52) U.S. Cl. 324/754

(57) ABSTRACT

A wafer test card applicable for testing all the chips on a wafer in one time simultaneously comprising a base board carrying testing circuit thereon and an electric conductive spring-rubber assembly connected to the underside of the base board; the electric conductive spring-rubber assembly has an electric insulating soft rubber layer which has an electric conductive spring matrix formed by a group of electric conductive springs arranged in rows and columns to form an electric connection with the testing circuit of the base board, and the electric conductive spring matrix of the electric conductive spring-rubber assembly is functioned as a wafer test interface to the wafer test card; during wafer test the electric conductive spring matrix of the wafer test card shall keep correctly touching and pressing against the pads of chips on a wafer to obtain more stable and reliable test result.

### BACKGROUND OF THE INVENTION

1. Field of the Invention

The invention relates to a wafer test card, especially the wafer test card with wafer test interface made of electric conductive spring-rubber assembly.

2. Description of the Prior Art

As illustrated in FIG. 1, the purpose of wafer test is to do electric property test over all chips 60 on a wafer 50 to screen out the defective chip. The conventional technique of wafer test includes employing a wafer probe card with probes on the card touching the pad on chip to form electrical connection, and then the testing signal is sent to Automatic Test Equipment (ATE) for analysis and judgment to obtain the result of electric property test of each chip 60 on the wafer 50.

As illustrated in FIG. 2, the structure of a conventional wafer probe card, such as the cantilever type probe card 10, comprises a base plate 11, a connecting plate 12 installed on the underside of the base plate 11 and plural cantilever probes 13 with flexibility formed on the connecting plate 12. Since the cantilever probe 13 of this cantilever type probe card 10 is flexible, it can touch the pad 61 on chip 60 to form electrical connection for testing the electric property of each chip 60.

However, this cantilever type probe card 10 has the following drawbacks:

First, since the cantilever probe 13 of the cantilever type probe card 10 is made of metal wire, and is installed by hand, the points of the cantilever probe 13 are very difficult to be arranged to form a flat surface, but are always located in the positions with fluctuating elevation.
Second, the cantilever probe 13 of the cantilever type probe card 10 needs a cantilever arm arranged in horizontal position. Therefore, the total number of cantilever probe 13 installed on the cantilever type probe card 10 is restricted. During wafer test, the chips 60 on the wafer 50 must be tested in batches and in separate times for testing the electric property. By using this cantilever type probe card 10, it is unable to test all the chips 60 on the wafer 50 in one time simultaneously.
Third, since the points of cantilever probes 13 are in the position with elevation different from each other, the marks cut into the pad 61 of each chips 60 by the points of cantilever probes 13 are different from each other that may cause error in chip identification or even cause damage of the pad 61 of chip 60 due to over pressure.

### SUMMARY OF THE INVENTION

In order to overcome the drawbacks of the conventional cantilever type probe card, the major purpose of the invention is to disclose a wafer test card which may test all the chips on a wafer in one time simultaneously to complete electric property test.

The structure of wafer test card of the invention comprises a base board and an electric conductive spring-rubber assembly connected to the underside of the base board, wherein the conductive spring-rubber assembly has a soft insulating layer which carries electric conductive springs arranged in matrix form of rows and columns, and each of the electric conductive springs is arranged to match the printed circuit on the base board to form electric connection; when carrying out electric property test the electric conductive spring matrix of the electric conductive spring-rubber assembly functions as testing interface of the wafer test card, and when the electric conductive spring matrix of electric conductive spring-rubber assembly of the wafer test card press against the pad on chips, owing to the protection by the soft insulating layer and the elastic cushion effect of the electric conductive spring, the damage of the pad on chip due to over contact pressure can be avoided, thus a more stable and reliable test result of electric property of wafer test can be achieved.

### BRIEF DESCRIPTION OF THE DRAWINGS

FIG. 1 is a schematic drawing for a conventional wafer.

FIG. 2 is a schematic drawing for a conventional cantilever type probe card which is for illustrating the tendency of causing test error by this cantilever type probe during wafer test.

FIG. 3 is a schematic drawing of a wafer test card of the present invention.

FIG. 4 is a sectional view of partial enlargement of the application of the invention on wafer test which shows how the wafer test card shown in FIG. 3 is to carry out electric property test on the chips of the whole wafer in one time simultaneously.

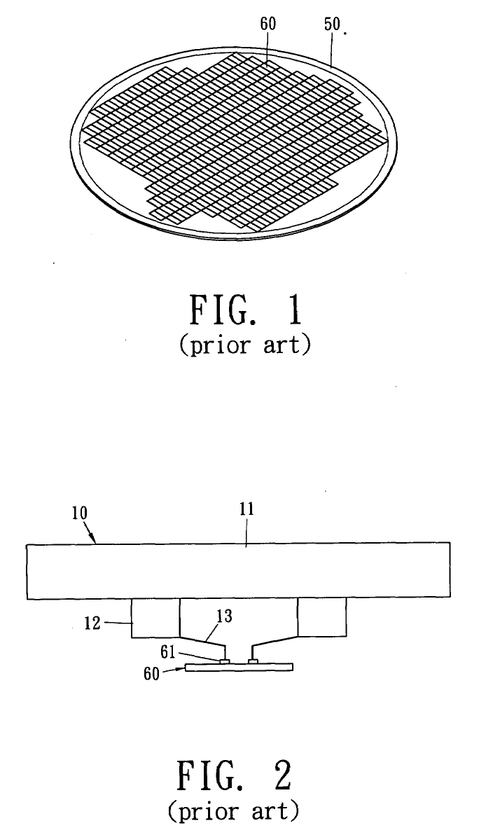

### DESCRIPTION OF THE PREFERRED EMBODIMENT

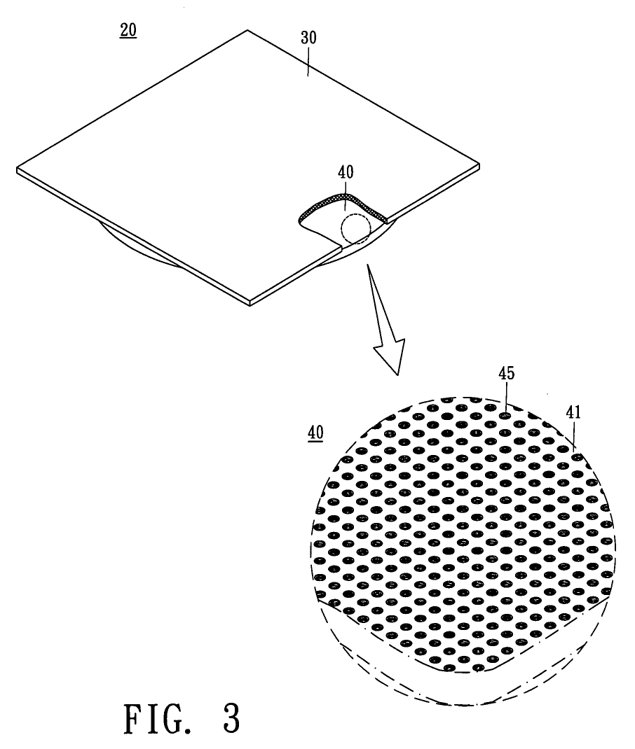

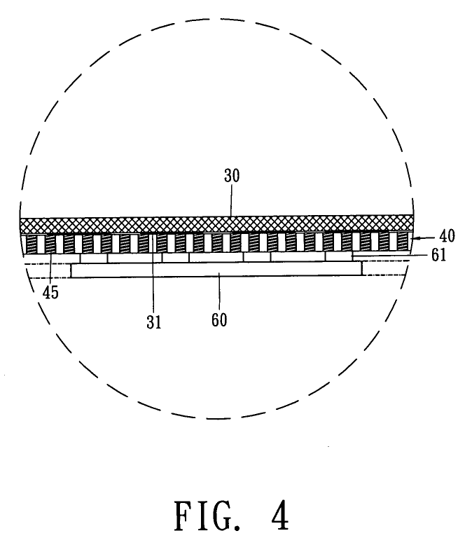

As shown in FIGS. 3 and 4, a wafer test card 20 of the present invention comprises a base board 30 and an electric conductive spring-rubber 40 connected to the underside of the base board 30. And, the based board 30 has test circuit 31 thereon for testing the electric property of the chips on a wafer.

The electric conductive spring-rubber assembly 40 has a soft insulating layer 41 which has an electric conductive spring matrix 45 formed by a group of electric conductive springs arranged in rows and columns. Each of the electric conductive springs of the electric conductive spring-rubber assembly 40 has the effect of conducting electric current and elastic cushion, and is wrapped and protected by the soft insulating layer 41, so that the electric conductive spring matrix 45 of the electric conductive spring-rubber assembly 40 will not be affected by external force to become slanting and bending over, and may be repeatedly used without affecting its normal function.

As shown in FIG. 4, the wafer test card 20 of the present invention has an electric conductive spring-rubber assembly 40 connected to the underside of the base board 30. The electric conductive spring matrix 45 on the electric conductive spring-rubber assembly 40 is arranged to touch the testing circuit 31 formed on the base board 30 to form electric connection. Therefore, when carrying out the wafer test, the electric conductive spring matrix on the electric conductive spring-rubber assembly 40 functions as wafer testing interface. Especially, the wafer test card 20 shall test all the chips 60 on a wafer in one time simultaneously to complete electric property test.

During wafer test, the electric conductive spring matrix 45 of the electric conductive spring-rubber assembly 40 of the wafer test card 20 of the invention touches the pad 61 on all the chips 60 on a wafer to form electric connection, and then the test signal sensed by the electric conductive spring matrix 45 are sent to automatic test equipment (ATE) through the testing circuit 31 of the base board 30 for analysis and judgment to obtain the electric property test result of all the chips 60 on wafer.

Besides, even the elevation of the pad 61 of each chip 60 are different from each other, the elastic cushion effect of the electric conductive spring-rubber assembly 40 may still enable the electric conductive spring matrix 45 correctly touching the pad 61 on chip 60 which in addition to avoiding damaging the pad 61 on chip 60 due to over pressure and also avoiding misidentifying the chip 60, thus the wafer test card 20 of the invention shall enable a more stable and reliable electric property test to a wafer.

What is claimed is:

1. A wafer test card comprises a base board carrying testing circuit thereon and an electric conductive spring-rubber assembly connected to the underside of the base board, wherein the electric conductive spring rubber assembly has a soft insulating layer which has an electric conductive spring matrix formed by a group of electric conductive springs arranged in rows and columns, and an electric connection is formed between the electric conductive spring-rubber assembly and the testing circuit on the based board through the electric conductive spring matrix.
